(19) United States
(12) Patent Application Publication
(10) Pub. No.: US 2023/0381916 A1
(43) Pub. Date: Nov. 30, 2023

(54) APPARATUS FOR POLISHING AND METHOD OF POLISHING

(71) Applicant: EBARA CORPORATION, Tokyo (JP)

(72) Inventors: Kuniaki YAMAGUCHI, Tokyo (JP); Dai YOSHINARI, Tokyo (JP); Kentaro ASANO, Tokyo (JP)

(21) Appl. No.: 18/323,658

(22) Filed: May 25, 2023

(30) Foreign Application Priority Data
May 27, 2022 (JP) 2022-087034

(51) Int. Cl. B24B 37/30; B24B 37/005

(52) U.S. Cl. CPC B24B 37/30; B24B 37/005

(57) ABSTRACT

One object is to suppress a substrate from being dried in the course of releasing the substrate from a substrate holding member in an apparatus for polishing. There is provided the apparatus for polishing, comprising: a polishing table configured to support a polishing pad; a substrate holding member having a substrate holding surface and a pressure chamber, which are made of an elastic membrane, wherein the pressure chamber has a plurality of areas arranged concentrically and a substrate is pressed against the polishing pad by a pressure in the pressure chamber; a pressure regulator configured to regulate a pressure of a gas that is supplied to the pressure chamber of the substrate holding member; one or a plurality of release nozzles configured to inject a pressurized fluid; and a control device configured to perform a substrate release process of releasing the substrate from the elastic membrane, the substrate release process controlling the pressure regulator to pressurize entirety of the elastic membrane by pressurizing all the areas in the pressure chamber and subsequently pressurize a center portion of the elastic membrane by pressurizing the pressure chamber such as to make a pressure in one or multiple areas on a center side, which include an area at a center of the pressure chamber, higher than pressures in other areas, wherein meanwhile the substrate release process controls the one or plurality of release nozzles to inject the pressurized fluid to a contact location between the elastic membrane and the substrate.

### TECHNICAL FIELD

The present disclosure relates to an apparatus for polishing and a method of polishing configured to polish a substrate such as a semiconductor wafer.

### BACKGROUND ART

In a manufacturing process of semiconductors, planarization technology of planarizing the surfaces of the semiconductor devices become increasingly important. The most important technique of this planarization technology is chemical mechanical polishing (CMP). This CMP technique performs polishing by bringing a substrate such as a wafer into sliding contact with a polishing surface with supplying a polishing solution containing abrasive grains such as silica (SiO₂) onto a polishing pad.

A polishing apparatus performing the CMP includes a polishing table configured to support a polishing pad having a polishing surface; and a substrate holing member called a top ring or the like and configured to hold a substrate. A procedure of polishing a substrate by using such a polishing apparatus presses the substrate against the polishing surface by a predetermined pressure, while holding the substrate by the top ring. The procedure of polishing then moves the polishing table and the top ring relative to each other, so as to bring the substrate into sliding contact with the polishing surface and perform flat and mirror polishing of the surface of the substrate.

In such a polishing apparatus, when a relative pressing force between the wafer and the polishing surface of the polishing pad during polishing is not uniform over the entire surface of the wafer, insufficient polishing or excessive polishing may occur according to the pressing forces applied to respective parts of the wafer. A measure taken to equalize the pressing force applied to the wafer provides a pressure chamber made of an elastic membrane (membrane) in a lower portion of a top ring and supply a gas such as the air to this pressure chamber. This polishes the substrate, while the substrate is pressed against the polishing surface of the polishing pad by the pressure of the gas.

After completion of the polishing process, the wafer on the polishing surface is vacuum-sucked to the top ring. The top ring with the wafer sucked thereto is moved up and is then moved to a position above a transfer or conveyance stage, where the wafer is released (separated) from the membrane. The release of the wafer is performed by injecting a release shower to a clearance between the wafer and the membrane with supplying the gas to the pressure chamber to swell the membrane (as described in PTL 1 and PTL 2).

### CITATION LIST

### Patent Literatures

PTL 1: Japanese Unexamined Patent Publication No. 2018-006549
PTL 2: Japanese Unexamined Patent Publication No. 2017-185589

### SUMMARY OF INVENTION

### Technical Problem

In the wafer release process described above, in the case where a fluid including a gas such as nitrogen gas is injected or sprayed as the release shower to a location between the membrane and the wafer, the surface of the wafer may be instantaneously dried to cause a defect (fault) in the wafer.

By taking into account the foregoing, one object of the present disclosure is to suppress a substrate from being dried in the course of releasing the substrate from a substrate holding member in a polishing apparatus.

### Solution to Problem

According to one aspect of the present disclosure, there is provided the apparatus for polishing, comprising: a polishing table configured to support a polishing pad; a substrate holding member having a substrate holding surface and a pressure chamber, which are made of an elastic membrane, wherein the pressure chamber has a plurality of areas arranged concentrically and a substrate is pressed against the polishing pad by a pressure in the pressure chamber; a pressure regulator configured to regulate a pressure of a gas that is supplied to the pressure chamber of the substrate holding member; one or a plurality of release nozzles configured to inject a pressurized fluid; and a control device configured to perform a substrate release process of releasing the substrate from the elastic membrane, the substrate release process controlling the pressure regulator to pressurize entirety of the elastic membrane by pressurizing all the areas in the pressure chamber and subsequently pressurize a center portion of the elastic membrane by pressurizing the pressure chamber such as to make a pressure in one or multiple areas on a center side, which include an area at a center of the pressure chamber, higher than pressures in other areas, wherein meanwhile the substrate release process controls the one or plurality of release nozzles to inject the pressurized fluid to a contact location between the elastic membrane and the substrate.

### BRIEF DESCRIPTION OF DRAWINGS

FIG. 1 is a plan view illustrating the overall configuration of a polishing apparatus according to one embodiment;

FIG. 2 is a schematic diagram illustrating the configuration of a polishing unit;

FIG. 3 is a schematic sectional view illustrating a top ring configuring a substrate holding member to hold a wafer as a polishing object and press the wafer against a polishing surface of a polishing table;

FIG. 4 is a schematic diagram illustrating the top ring and a substrate transfer apparatus (pusher);

FIG. 5 is a schematic diagram illustrating the detailed structure of the pusher;

FIG. 6 is a fluid circuit diagram of a pressurized fluid that is to be supplied to release nozzles;

FIG. 7 is a plan view of the pusher showing directions of the release nozzles;

FIG. 8A is an explanatory view illustrating release of a substrate from the top ring;

FIG. 8B is an explanatory view illustrating release of the substrate from the top ring;

FIG. 8C is an explanatory view illustrating release of the substrate from the top ring;

FIG. 8D is an explanatory view illustrating release of the substrate from the top ring;

FIG. 9A is a time chart showing a substrate release process according to a comparative example;

FIG. 9B is a time chart showing a substrate release process according to the embodiment;

FIG. 10 is a flowchart showing the substrate release process according to the embodiment;

FIG. 11 is a diagram illustrating a measurement example that measures a difference in wafer release time by the injection start timing of the pressurized fluid; and

FIG. 12 is a diagram illustrating a measurement example that measures a difference in wafer release time by the directions of the release nozzles.

### DESCRIPTION OF EMBODIMENTS

The following describes an embodiment with referring to the drawings. A substrate processing apparatus 100 according to this embodiment is a polishing apparatus configured to polish substrates, as one example. This embodiment is described with wafers referring to as one example of the substrates. The present disclosure is, however, applicable to any substrates other than the wafers (for example, glass substrates and printed circuit boards).

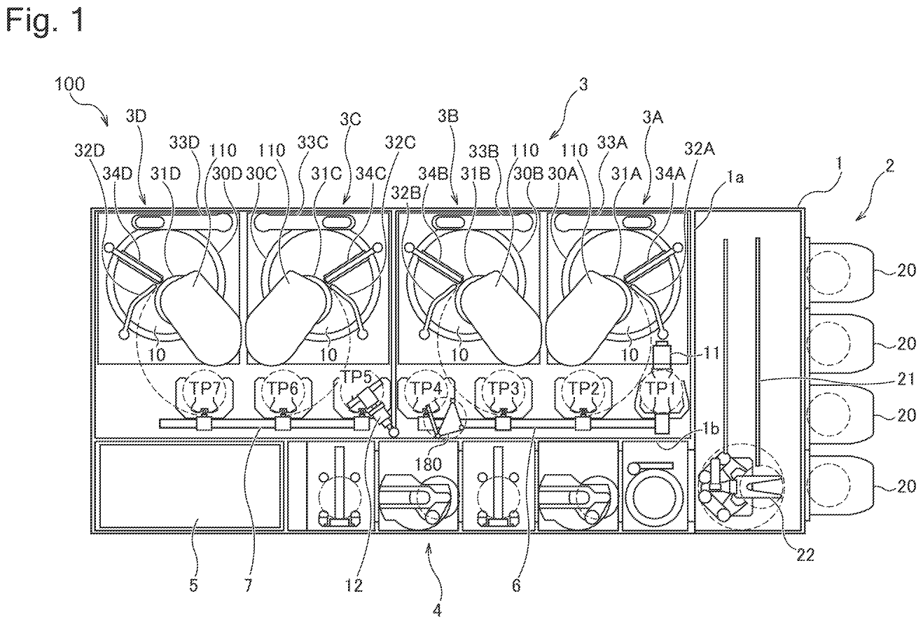

FIG. 1 is a plan view illustrating the overall configuration of the substrate processing apparatus 100 according to one embodiment of the present disclosure. As shown in FIG. 1, this substrate processing apparatus 100 includes a housing 1 in an approximately rectangular shape. Inside of the housing 1 is parted to a loading/unloading module 2, a polishing module 3, and a cleaning module 4 by partition walls 1a and 1b. The loading/unloading module 2, the polishing module 3 and the cleaning module 4 are assembled independently of one another and are evacuated independently of one another. The substrate processing apparatus 100 also includes a control device 5 configured to control substrate processing operations.

The loading/unloading module 2 includes two or more (four according to the embodiment) front loading units 20 which wafer cassettes stocked with a large number of wafers (substrates) are respectively mounted thereon. These front loading units 20 are arranged adjacent to the housing 1 and are arrayed along a width direction (a direction perpendicular to a longitudinal direction) of the substrate processing apparatus 100. An open cassette, an SMIF (standard manufacturing interface) pod or an FOUP (front opening unified pod) may be mounted on each of the front loading units 20. The SMIF pod and FOUP herein are closed containers configured to place a wafer cassette inside thereof and covered with a partition wall to maintain an environment independent of the outside space.

In the loading/unloading module 2, a traveling mechanism 21 is laid along the array of the front loading units 20, and a transfer robot (loader) 22 is placed on this traveling mechanism 21 to be movable along an array direction of the wafer cassettes. The transfer robot 22 moves on the traveling mechanism 21 to access the wafer cassettes mounted on the front loading units 20. The transfer robot 22 has two hands respectively provided on an upper side and on a lower side and is allowed to use the upper hand and the lower hand separately: using the upper hand to return each processed wafer to the wafer cassette and using the lower hand to take out each unprocessed wafer or each wafer to be processed, from the wafer cassette. Additionally, the lower hand of the transfer robot 22 is configured to rotate around a shaft center thereof and thereby invert the wafer.

The loading/unloading module 2 is an area that requires to maintain the cleanest state, so that the inside of the loading/unloading module 2 is continuously kept at higher pressure than the pressures of all of the outside of the substrate processing apparatus 100, the polishing module 3 and the cleaning module 4. The polishing module 3 uses a slurry as a polishing solution and is accordingly a dirtiest area. Accordingly, a negative pressure is formed inside of the polishing module 3, and the internal pressure of the polishing module 3 is kept lower than the internal pressure of the cleaning module 4. The loading/unloading module 2 is provided with a filter fan unit (not shown) that includes a clean air filter, such as an HEPA filter, a ULPA filter or a chemical filter and that is configured to continuously blow off the clean air after exclusion of particles, toxic vapors, and toxic gases.

The polishing module 3 is an area where polishing (flattening) of the wafers is performed and includes a first polishing unit 3A, a second polishing unit 3B, a third polishing unit 3C and a fourth polishing unit 3D. The first polishing unit 3A, the second polishing unit 3B, the third polishing unit 3C and the fourth polishing unit 3D are arranged, for example, along the longitudinal direction of the substrate processing apparatus 100 as shown in FIG. 1.

As shown in FIG. 1, the first polishing unit 3A includes a polishing table 30A with a polishing pad 10 that is mounted thereon and that has a polishing surface; a top ring (substrate holding member) 31A configured to hold a wafer and to press the wafer against the polishing pad 10 on the polishing table 30A so as to polish the wafer; a polishing solution supply nozzle 32A configured to supply a polishing solution or a dressing solution (for example, pure water such as DIW) to the polishing pad 10; a dresser 33A configured to perform dressing of the polishing surface of the polishing pad 10; and an atomizer 34A configured to atomize a fluid mixture of a liquid (for example, pure water such as DIW) and a gas (for example, nitrogen gas), or a liquid (for example, pure water such as DIW), and inject or spray the atomized fluid mixture or liquid to the polishing surface.

Similarly, the second polishing unit 3B includes a polishing table 30B with a polishing pad 10 mounted thereon; a top ring (substrate holding member) 31B; a polishing solution supply nozzle 32B; a dresser 33B; and an atomizer 34B. The third polishing unit 3C includes a polishing table 30C with a polishing pad 10 mounted thereon; a top ring (substrate holding member) 31C; a polishing solution supply nozzle 32C; a dresser 33C; and an atomizer 34C. The fourth polishing unit 3D includes a polishing table 30D with a polishing pad 10 mounted thereon; a top ring (substrate holding member) 31D; a polishing solution supply nozzle 32D; a dresser 33D; and an atomizer 34D.

The following describes a transfer mechanism configured to convey or transfer the wafer. As shown in FIG. 1, a first linear transporter 6 is placed adjacent to the first polishing unit 3A and the second polishing unit 3B. This first linear transporter 6 is a mechanism of conveying or transferring each wafer between four transfer or conveyance positions along the direction of the array of the first polishing unit 3A and the second polishing unit 3B (the four transfer positions are referred to as a first transfer position TP1, a second transfer position TP2, a third transfer position TP3, and a fourth transfer position TP4 sequentially aligned from a loading/unloading module side).

A second linear transporter 7 is placed adjacent to the third polishing unit 3C and the fourth polishing unit 3D. This second linear transporter 7 is a mechanism of conveying or transferring each wafer between three transfer or conveyance positions along the direction of the array of the third polishing unit 3C and the fourth polishing unit 3D (the three transfer positions are referred to as a fifth transfer position TP5, a sixth transfer position TP6, and a seventh transfer position TP7 sequentially aligned from the loading/unloading module side).

The wafer is conveyed to the first polishing unit 3A and the second polishing unit 3B by the first linear transporter 6. The top ring 31A of the first polishing unit 3A is moved between a polishing position and the second transfer position TP2 by a swing action of a top ring head 110. Accordingly, the wafer is transferred to the top ring 31A at the second transfer position TP2. Similarly, the top ring 31B of the second polishing unit 3B is moved between a polishing position and the third transfer position TP3, and the wafer is transferred to the top ring 31B at the third transfer position TP3. The top ring 31C of the third polishing unit 3C is moved between a polishing position and the sixth transfer position TP6, and the wafer is transferred to the top ring 31C at the sixth transfer position TP6. The top ring 31D of the fourth polishing unit 3D is moved between a polishing position and the seventh transfer position TP7, and the wafer is transferred to the top ring 31D at the seventh transfer position TP7.

A lifter 11 is placed at the first transfer position TP1 to receive the wafer from the transfer robot 22. The wafer is transferred from the transfer robot 22 to the first linear transporter 6 via this lifter 11. A shutter (not shown) is provided in the partition wall 1a to be placed between the lifter 11 and the transfer robot 22 and is opened in the course of conveyance of the wafer to transfer the wafer from the transfer robot 22 to the lifter 11. A swing transporter 12 is placed between the first linear transporter 6 and the second linear transporter 7 and the cleaning module 4. This swing transporter 12 is provided with a hand that is movable between the fourth transfer position TP4 and the fifth transfer position TP5. The wafer is transferred from the first linear transporter 6 to the second linear transporter 7 by the swing transporter 12. The wafer is conveyed to the third polishing unit 3C and/or the fourth polishing unit 3D by the second linear transporter 7. The wafer polished in the polishing module 3 is conveyed via the swing transporter 12 to the cleaning module 4, is washed and dried in the cleaning module 4 and is then transferred to the transfer robot 22.

The configuration of the polishing apparatus described above is only illustrative, and another configuration may be employed as the configuration of the polishing apparatus. The substrate processing apparatus 100 may be an apparatus other than the polishing apparatus.

[Polishing Unit]

The following describes the polishing unit more in detail. The first polishing unit 3A, the second polishing unit 3B, the third polishing unit 3C and the fourth polishing unit 3D have identical configurations with one another. The first polishing unit 3A is accordingly described below.

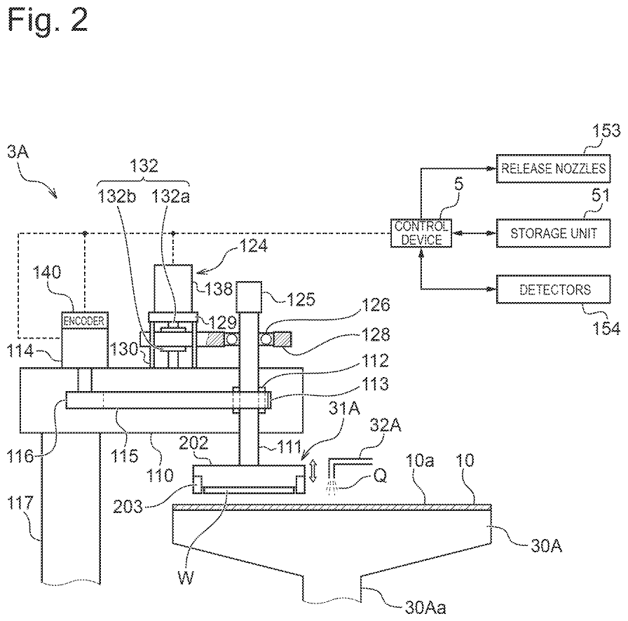

FIG. 2 is a schematic diagram illustrating the configuration of the first polishing unit 3A according to the embodiment. As shown in FIG. 2, the first polishing unit 3A includes the polishing table 30A and the top ring 31A configured to hold a substrate, for example, a wafer, as a polishing object or an object to be polished and to press the substrate against the polishing surface on the polishing table 30A.

The polishing table 30A is connected via a table shaft 30Aa with a motor (not shown) that is placed below the polishing table 30A to be rotatable about this table shaft 30Aa. The polishing pad 10 is applied on an upper face of the polishing table 30A. A polishing surface 10a of the polishing pad 10 forms a polishing surface serving to polish a wafer W. A polishing solution supply nozzle 32A is placed above the polishing table 30A. A polishing solution Q is supplied onto the polishing pad 10 on the polishing table 30A by this polishing solution supply nozzle 32A.

The top ring 31A is basically comprised of: a top ring main body 202 configured to press the wafer W against the polishing surface 10a; and a retainer ring 203 configured to hold an outer periphery of the wafer W and prevent the wafer W from being protruded from the top ring 31A.

The top ring 31A is connected with a top ring shaft 111, which is configured to be vertically moved or moved up and down relative to the top ring head 110 by a vertical moving mechanism 124. The entire top ring 31A is lifted up and down to be positioned relative to the top ring head 110 by vertically moving this top ring shaft 111. A rotary joint 125 is attached to an upper end of the top ring shaft 111.

The vertical moving mechanism 124 configured to move up and down or vertically move the top ring shaft 111 and the top ring 31A includes a bridge 128 provided to support the top ring shaft 111 in a rotatable manner via a bearing 126; a ball screw 132 attached to the bridge 128; a support base 129 supported by a supporting column 130; and a servomotor 138 provided on the support base 129. The support base 129 that supports the servomotor 138 is fixed to the top ring head 110 via the supporting column 130.

The ball screw 132 includes a threaded shaft 132a connected with the servomotor 138; and a nut 132b which this threaded shaft 132a is screwed into. The top ring shaft 111 is integrated with the bridge 128 to be moved up and down. Accordingly, driving the servomotor 138 vertically moves the bridge 128 via the ball screw 132, so as to vertically move the top ring shaft 111 and the top ring 31A.

The top ring shaft 111 is connected with a rotary cylinder 112 via a key (not shown). This rotary cylinder 112 is provided with a timing pulley 113 on an outer circumferential portion thereof. A top ring rotating motor 114 is fixed to the top ring head 110. The timing pulley 113 is connected with a timing pulley 116 provided on the top ring rotating motor 114 via a timing belt 115. Accordingly, rotation driving of the top ring rotating motor 114 causes the rotary cylinder 112 and the top ring shaft 111 to be rotated integrally via the timing pulley 116, the timing belt 115 and the timing pulley 113, so as to rotate the top ring 31A. The top ring rotating motor 114 is provided with an encoder 140. The encoder 140 has a function of detecting a rotation angle position of the top ring 31A and a function of integrating the number of rotations of the top ring 31A. A sensor of detecting a rotation angle of the top ring 31A “reference position (0 degree)” may be provided separately. The top ring head 110 is supported by a top ring head shaft 117 that is supported by a frame (not shown) in a rotatable manner.

The control device 5 is configured to control the respective devices included in the apparatus, for example, the top ring rotating motor 114, the servomotor 138 and the encoder 140. A storage unit 51 is connected with the control device 5 by wire or wirelessly, so that the control device 5 is allowed to refer to the storage unit 51. Programs for controlling substrate processing operations, various parameters and the like are stored in the storage unit 51. The storage unit 51 includes a volatile and/or nonvolatile memory.

In the first polishing unit 3A configured as shown in FIG. 2, the top ring 31A is configured to hold a substrate such as the wafer W on a lower face thereof. The top ring head 110 is configured to be turnable or swingable about the top ring head shaft 117. Turning or swinging the top ring head 110 causes the top ring 31A with the wafer W held on the lower face thereof to be moved from a wafer W receiving position or a position where the wafer W is received to above the polishing table 30A. The top ring 31A is then moved down to press the wafer W against the surface (polishing surface) 10a of the polishing pad 10. The top ring 31A and the polishing table 30A are respectively rotated, and the polishing solution is supplied from the polishing solution supply nozzle 32A provided above the polishing table 30A onto the polishing pad 10. The wafer W is brought into sliding contact with the polishing surface 10a of the polishing pad 10 as described above, so that the surface of the wafer W is polished.

[Top Ring]

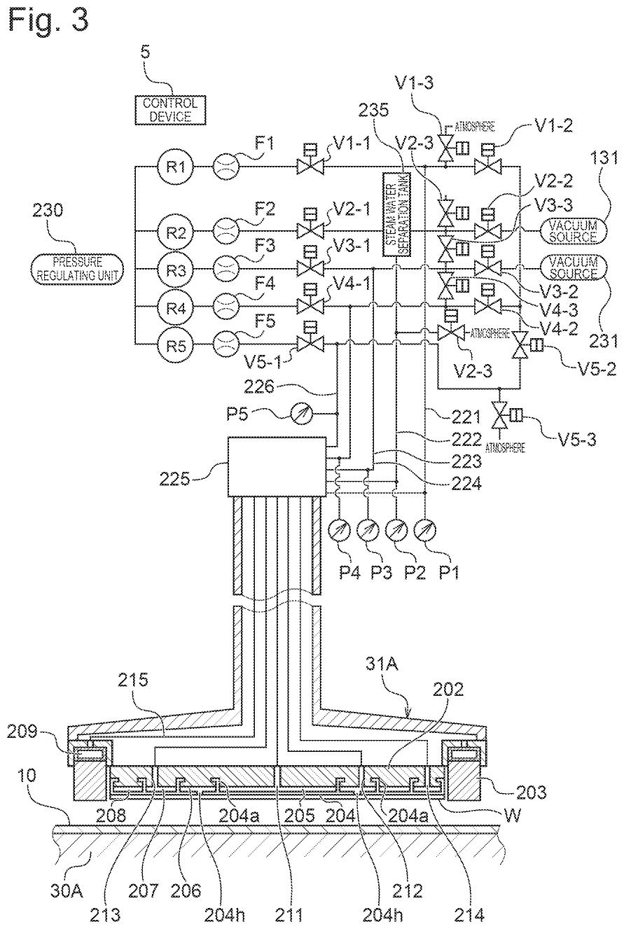

The following describes the top ring (substrate holding member) included in the polishing apparatus of the present disclosure. FIG. 3 is a schematic sectional view illustrating the top ring 31A that configures a substrate holding member or a substrate holding device to hold the wafer W as the polishing object and press the wafer W against the polishing surface on the polishing table. Only primary components of the top ring 31A are illustrated in FIG. 3.

As shown in FIG. 3, the top ring 31A is basically comprised of the top ring main body (also called carrier) 202 configured to press the wafer W against the polishing surface 10a; and the retainer ring 203 configured to directly press the polishing surface 10a. The top ring main body (carrier) 202 is formed by a substantially disk-shaped member, and the retainer ring 203 is attached to an outer peripheral portion of the top ring main body 202. The top ring main body 202 is made of a resin such as an engineering plastic (for example, PEEK). An elastic membrane (membrane) 204 that comes into contact with a rear face of the wafer is attached to a lower face of the top ring main body 202. The elastic membrane (membrane) 204 is made of a rubber material having excellent strength and excellent durability, for example, ethylene propylene rubber (EPDM), polyurethane rubber or silicone rubber.

The elastic membrane (membrane) 204 has a plurality of partition walls 204a that are arranged concentrically to form a pressure chamber consisting of a plurality of areas/rooms between an upper face of the elastic membrane 204 and the lower face of the top ring main body 202. This pressure chamber includes a first area 205 that is a circular chamber, a second area 206 that is a ring-shaped chamber, a third area 207 that is a ring-shaped chamber, and a fourth area 208 that is a ring-shaped chamber. More specifically, the first area 205 is formed in a center portion or at the center of the top ring main body 202, and the second area 206, the third area 207 and the fourth area 208 are concentrically arranged and sequentially formed in a direction from the center toward the outer circumference. In the illustrated example, four areas are formed inside of the elastic membrane 204. The number of the areas may, however, be three or less or may be five or more (for example, eight).

The elastic membrane (membrane) 204 has a plurality of holes 204h for suction of the wafer that are pierced in a thickness direction of the elastic membrane and that are provided in the second area 206. The holes 204h are provided in the second area according to the embodiment but may be provided in a location other than the second area. A modified configuration may not provide a plurality of holes for suction of the wafer in the elastic membrane 204 but may cause the wafer to be adsorbed by the adsorptive property of the rubber material of the elastic membrane 204 and expansion/contraction of the elastic membrane 204.

A flow path 211 communicating with the first area 205, a flow path 212 communicating with the second area 206, a flow path 213 communicating with the third area 207 and a flow path 214 communicating with the fourth area 208 are formed inside of the top ring main body 202. The flow path 211 communicating with the first area 205, the flow path 213 communicating with the third area 207 and the flow path 214 communicating with the fourth area 208 are respectively connected with a flow path 221, a flow path 223 and a flow path 224 via a rotary joint 225. The flow paths 221, 223 and 224 are respectively connected with a pressure regulating unit 230 via valves V1-1, V3-1 and V4-1 and pressure regulators (for example, electropneumatic regulators) R1, R3 and R4. The flow paths 221, 223 and 224 are also respectively connected with a vacuum source 231 via valves V1-2, V3-2 and V4-2 and are respectively allowed to communicate with the atmosphere via valves V1-3, V3-3 and V4-3.

The flow path 212 communicating with the second area 206 is, on the other hand, connected with a flow path 222 via the rotary joint 225. The flow path 222 is connected with the pressure regulating unit 230 via a steam water separation tank 235, a valve V2-1 and a pressure regulator (for example, electropneumatic regulator) R2. The flow path 222 is also connected with a vacuum source 131 via the steam water separation tank 235 and a valve V2-2 and is allowed to communicate with the atmosphere via a valve V2-3. The pressure regulators R1 to R4 are connected with the control device 5. The control device 5 controls the pressure regulators R1 to R4 to change the pressures of the gas supplied to the respective areas inside of the membrane 204.

This configuration of changing the pressures in the respective chambers inside of the membrane 204 controls the swelling of the membrane 204 and enables the wafer W sucked to the membrane 204 to be released (separated) from the membrane 204. For example, the configuration of changing the pressures of the gas supplied into the membrane 204 according to the sticking force of the wafer W to the membrane 204 controls the swelling of the membrane 204 and stabilizes a time period required for releasing the wafer W from the membrane 204 (hereinafter may be referred to as wafer release time). For example, changing the pressures inside of the membrane 204 achieves a change to an appropriate pressure for the wafer W and thereby reduces the stress placed on the wafer W.

A retainer ring compression chamber 209 made of an elastic membrane is formed immediately above the retainer ring 203. The retainer ring compression chamber 209 is connected with a flow path 226 via a flow path 215 formed inside of the top ring main body (carrier) 202 and via the rotary joint 225. The flow path 226 is connected with the pressure regulating unit 230 via a valve V5-1 and a pressure regulator (for example, electropneumatic regulator) R5. The flow path 226 is also connected with the vacuum source 231 via a valve V5-2 and is allowed to communicate with the atmosphere via a valve V5-3. The retainer ring compression chamber 209 is used as a retainer ring pressing mechanism according to the embodiment. The retainer ring pressing mechanism may, however, be a fluid actuator using the air, water, oil or the like, an electric actuator using a ball screw or the like, or an elastic member including a spring and a bag-like portion.

The pressure regulators R1, R2, R3, R4 and R5 respectively have pressure regulating functions to regulate the pressures of a pressurized fluid supplied from the pressure regulating unit 230 to the first area 205, to the second area 206, to the third area 207, to the fourth area 208 and to the retainer ring compression chamber 209. The pressure regulators R1, R2, R3, R4 and R5 and the respective valves V1-1 to V1-3, V2-1 to V2-3, V3-1 to V3-3, V4-1 to V4-3 and V5-1 to V5-3 are connected with the control device 5 (shown in FIG. 1 and FIG. 2), which controls the operations of the respective pressure regulators and valves. Pressure sensors P1, P2, P3, P4, and P5 and flow rate sensors F1, F2, F3, F4 and F5 are placed respectively in the flow paths 221, 222, 223, 224 and 226.

In the top ring 31A configured as shown in FIG. 3, as described above, the first area 205 is formed in the center portion or at the center of the top ring main body 202, and the second area 206, the third area 207 and the fourth area 208 are concentrically arranged and sequentially formed in the direction from the center toward the outer circumference. The pressures of the fluid supplied to the first area 205, to the second area 206, to the third area 207, to the fourth area 208 and to the retainer ring compression chamber 209 are independently regulated by the pressure regulating unit 230 and the pressure regulators R1, R2, R3, R4, and R5. This configuration enables the pressing force for pressing the wafer W against the polishing pad 10 to be regulated in each of the areas of the wafer W and also enables the pressing force for pressing the retainer ring 203 against the polishing pad 10 to be regulated.

The following describes a series of polishing process performed by the substrate processing apparatus 100 configured as shown in FIGS. 1 to 3. The top ring 31A receives the wafer W from the first linear transporter 6 and holds the wafer W by vacuum suction. The elastic membrane (membrane) 204 is provided with the plurality of holes 204h for vacuum suction of the wafer W, and these holes 204h are communicated with the vacuum source 131. The top ring 31A with the wafer W held by vacuum suction is moved down to a polishing-time set position of the top ring that is set in advance. At this polishing-time set position, the retainer ring 203 is grounded to the surface (polishing surface) 10a of the polishing pad 10. Prior to polishing, the wafer W is sucked and held by the top ring 31A, so that there is a slight clearance (for example, about 1 mm) between a lower face (a surface to be polished) of the wafer W and the surface (polishing surface) 10a of the polishing pad 10. At this time, both the polishing table 30A and the top ring 31A are driven to rotate. In this state, the elastic membrane (membrane) 204 placed on the rear face side of the wafer W is swollen, so as to bring the lower face (the surface to be polished) of the wafer W into contact with the surface (polishing surface) 10a of the polishing pad 10. The polishing table 30A and the top ring 31A are moved relative to each other, and the wafer W is polished until the surface (surface to be polished) of the wafer W becomes a predetermined state (for example, a predetermined film thickness).

After completion of this wafer treatment process on the polishing pad 10, the membrane 204 is contracted, and the wafer W is vacuum sucked to the top ring 31A. The top ring 31A is then moved up and is moved to a substrate transfer apparatus (for example, a pusher) 150 provided in the first linear transporter (substrate transporting module) 6. After such moving, a gas (for example, nitrogen) is supplied to the respective areas inside of the membrane 204, so as to swell the membrane 204 to a predetermined degree and reduce the sticking area of the membrane 204 to the wafer W. A pressurized fluid is then blown between the membrane 204 and the wafer W. This releases the wafer W from the membrane 204. The release or separation of the wafer W from the membrane 204 may be referred to as wafer release. The following describes the details of this wafer release.

The predetermined degree to which the membrane 204 is swollen denotes a degree that causes the position of the wafer W to be a position where the pressurized fluid is injectable or sprayable from release nozzles (described later) to the rear face of the wafer W. In one example, the membrane 204 is swollen to make the height of the rear face of the wafer W substantially equal to the height of release nozzles 153 or slightly lower than the height of the release nozzles 153. This causes the pressurized fluid injected from the release nozzles 153 to enter between the membrane and the wafer, to hit against the membrane (and/or the rear face of the wafer), and to be supplied to a contact location between the membrane and the wafer.

[Pusher]

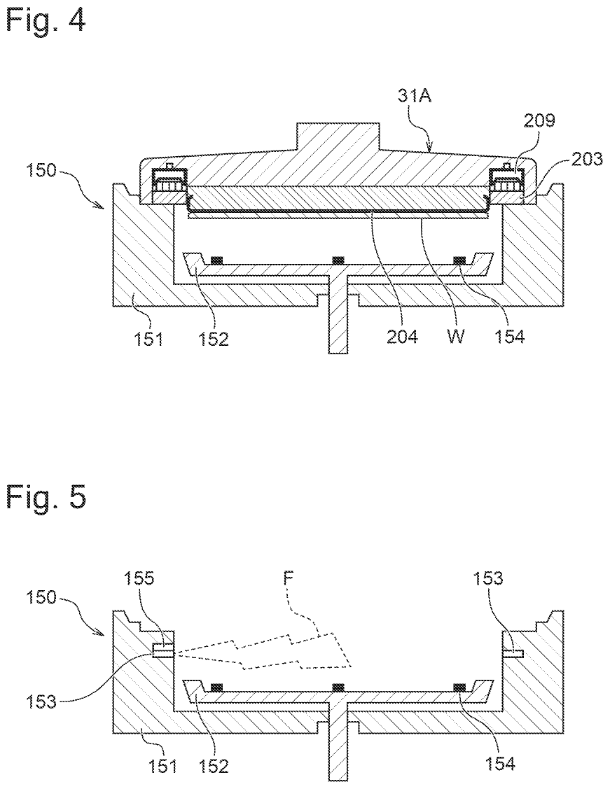

FIG. 4 is a schematic diagram illustrating the top ring 31A and the pusher 150. This illustrates the state that the pusher 150 is moved up, in order to transfer the wafer W from the top ring 31A to the pusher 150. As shown in FIG. 4, the pusher 150 includes a top ring guide 151 configured to be fit in an outer circumferential surface of the top ring 31A for the purpose of centering between the pusher 150 and the top ring 31A; a push stage 152 configured to support the wafer in the process of transferring the wafer between the top ring 31A and the pusher 150; an air cylinder (not shown) configured to move up and down the push stage 152; and an air cylinder (not shown) configured to move up and down the push stage 152 and the top ring guide 151. One or a plurality of (for example, three) seating sensors 154 are provided on the push stage 152 to detect that the wafer W released from the membrane 204 is placed on the push stage 152 and thereby detect a wafer release. The seating sensors 154 are, for example, contact sensors. The number of the seating sensors may be two or less or may be four or more. According to the embodiment, the wafer release is detected by the seating sensors 154. A modified configuration may monitor the pressures in the pressure chamber of the membrane 204 so as to detect a wafer release.

The following describes the operations of transferring the wafer W from the top ring 31A to the pusher 150. After completion of the wafer treatment process on the polishing pad the top ring 31A holds the wafer W by suction. The suction of the wafer W is implemented by making the holes 204h of the membrane 204 communicate with the vacuum source 131. The top ring 31A has the membrane 204 with the holes 204h provided in the surface thereof to suck the wafer W via these holes 204h as described above, so that the wafer W is sucked to the surface of the membrane 204.

After suction of the wafer W, the top ring 31A is moved up and is moved to the pusher 150 to release (separate) the wafer W. After the top ring 31A is moved to the pusher 150, a cleaning operation may be performed by rotating the top ring 31A with supplying pure water or a chemical solution to the wafer W sucked and held by the top ring 31A.

The push stage 152 and the top ring guide 151 of the pusher 150 are then moved up, and the top ring guide 151 is fit in the outer circumferential surface of the top ring 31A to achieve centering between the top ring 31A and the pusher 150. In this state, the top ring guide 151 pushes up the retainer ring 203. Simultaneous evacuation of the retainer ring compression chamber 209 accelerates the move-up of the retainer ring 203. After completion of the move-up of the pusher 150, a bottom face of the retainer ring 203 is pressed by an upper face of the top ring guide 151 to be pushed up to above a lower face of the membrane 204, so that a location between the wafer and the membrane is exposed. In the illustrated example of FIG. 4, the bottom face of the retainer ring 203 is located above the lower face of the membrane 204 by a predetermined height (for example, 1 mm). The vacuum suction of the wafer W by the top ring 31A is then stopped, and a wafer release operation (process) is performed. A modification may change the positional relationship between the pusher and the top ring to the desired positional relationship by moving down the top ring, instead of moving up the pusher.

FIG. 5 is a schematic diagram illustrating the detailed structure of the pusher 150. As shown in FIG. 5, the pusher 150 includes the top ring guide 151, the push stage 152 and two release nozzles (substrate separation accelerators) 153 formed inside of the top ring guide 151 and configured to inject a pressurized fluid F. The pressurized fluid F may be only a pressurized gas (for example, pressurized nitrogen), may be only a pressurized liquid (for example, pressurized water), or may be a fluid mixture of a pressurized gas (for example, pressurized nitrogen) and a liquid (for example, pure water). The release nozzles 153 are connected with the control device 5 via control lines or the like and are controlled by the control device 5. Furthermore, the pusher 150 is provided with a position detector 155 configured to detect the position of the wafer W sucked to the membrane 204. According to the embodiment, the position detector 155 is configured to detect the height of a rear face of the wafer W sucked to the membrane 204. The position detector 155 is provided with, for example, an imaging unit to take an image of the inside of the top ring guide 151 and is configured to detect the height of the rear face of the wafer W from the taken image. The position detector 155 may, however, be omitted.

A plurality of the release nozzles 153 are provided at a predetermined interval in a circumferential direction of the top ring guide 151 and are configured to inject the pressurized fluid F inward in a radial direction of the top ring guide 151 and toward the center of the top ring guide 151. This configuration injects a release shower made of the pressurized fluid F between the wafer W and the membrane 204 and performs the wafer release to release or separate the wafer W from the membrane 204.

[Fluid Supply Module to Release Nozzles]

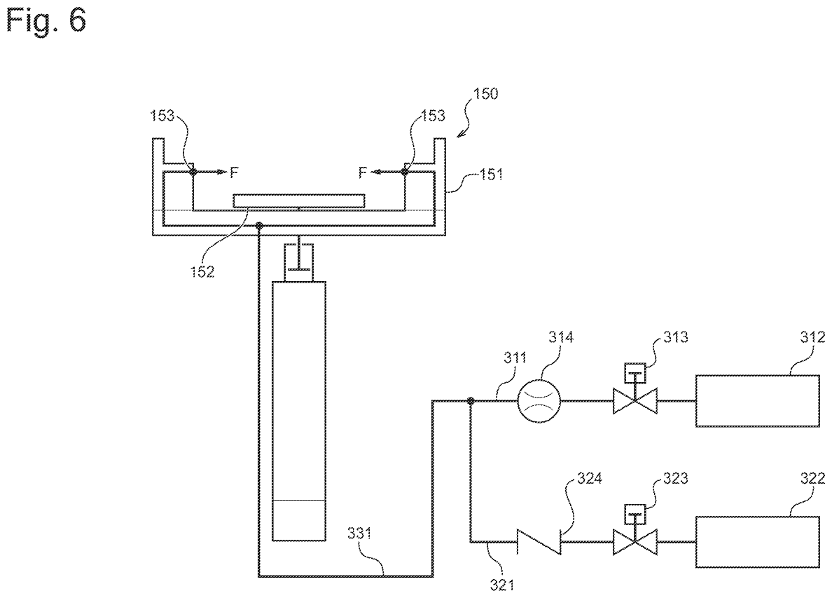

FIG. 6 is a fluid circuit diagram of the pressurized fluid F that is supplied to the release nozzles 153. The release nozzles 153 are connected with a flow path 331. The flow path 331 is branched off to a flow path 311 and a flow path 321 and is connected with a liquid supply source 312 via the flow path 311 while being connected with a gas supply source 322 via the flow path 321. The liquid supply source 312 may be a supply source configured to supply, for example, pure water such as DIW or another liquid that does not affect the semiconductor process. The gas supply source 322 may be a supply source configured to supply, for example, an inert gas such as nitrogen gas or another gas that does not affect the semiconductor process. The configuration described herein is allowed to supply the liquid and/or the gas as the pressurized fluid F, but the piping structure employed may be a configuration of supplying only the liquid or a configuration of supplying only the gas.

The liquid supply source 312 supplies a liquid of a predetermined pressure or a liquid adjusted to a predetermined pressure. A valve 313 and a flowmeter 314 are provided in the flow path 311 connected with the liquid supply source 312. The valve 313 may be a gate valve or a flow control valve controlled by the control device 5. The flowmeter 314 may be, for example, a Karman vortex flowmeter or a differential pressure type flowmeter. The liquid supply source 312 is configured to supply the liquid adjusted to the predetermined pressure to the valve 313. The liquid supply source 312 may include, for example, a utility line in a factory or the like, a flow path connected with the utility line in the factory or the like, and/or a pressure regulator, a flow control valve and the like connected with the utility line in the factory or the like (not shown). The valve 313 may be directly connected with the utility line in the factory or the like. Opening the valve 313 enables the liquid of the predetermined pressure to be supplied from the liquid supply source 312 through the flow path 311 to the flow path 331.

The gas supply source 322 supplies a gas of a predetermined pressure or a gas adjusted to a predetermined pressure. A valve 323 and a check valve 324 are provided in a flow path 321 connected with the gas supply source 322. The valve 323 may be a gate valve or a flow control valve controlled by the control device 5. The gas supply source 322 is configured to supply the gas adjusted to the predetermined pressure to the valve 323. The gas supply source 322 may include, for example, a utility line in a factory or the like, a flow path connected with the utility line in the factory or the like, and/or a pressure regulator, a flow control valve and the like connected with the utility line in the factory or the like (not shown). The valve 323 may be directly connected with the utility line in the factory or the like. Opening the valve 323 enables the gas of the predetermined pressure to be supplied from the gas supply source 322 through the flow path 321 to the flow path 331.

In the configuration described above, closing the valve 323 and opening only the valve 313 enables only the liquid as the pressurized fluid F to be injected from the release nozzles 153. In the configuration described above, on the other hand, closing the valve 313 and opening only the valve 323 enables only the gas as the pressurized fluid F to be injected from the release nozzles 153. The configuration described above also enables both the liquid and the gas as the pressurized fluid F to be injected from the release nozzles 153.

In one example, after only the valve 313 is opened to fill the flow path 331 with the liquid (for example, DIW), only the valve 323 is opened to cause the liquid (for example, DIW) filled in the flow path 331 to be injected from the release nozzles 153 by the gas (for example, nitrogen gas) supplied from the gas supply source 322. In this case, the pressurized fluid F is a fluid mixture of the liquid (for example, DIW) and the gas (for example, nitrogen gas). The pressure of the gas (for example, nitrogen gas) supplied from the gas supply source 322 may be set higher than the pressure of the liquid (for example, DIW) supplied from the liquid supply source 312. For example, the pressure of the liquid (for example, DIW) may be set to 0.2 MPa, and the pressure of the gas (for example, nitrogen gas) may be set to 0.4 MPa. In the case where there is a pressure difference between the liquid and the gas, it is not preferable to open the valve 313 and the valve 323 simultaneously, because of the reason described later. The configuration of this embodiment accordingly first fills the flow path 331 with only the liquid and subsequently supplies the gas to the flow path 331 with stopping the supply of the liquid as described above. This causes the gas to push out and inject or spray the liquid. In this state, in order to prevent the liquid filled in the flow path from being used up prior to the wafer release and thereby prevent only the gas from being injected to the wafer, an injection start timing of the pressurized fluid is adjusted, based on a membrane swelling start timing. This effectively suppresses the wafer from being dried.

A conventional configuration simultaneously opens the valves 323 and 313, which are respectively connected with the gas supply source 322 and with the liquid supply source 312 having different pressures, to inject the fluid mixture of the gas and the liquid from the release nozzles. In this case, however, there may be a pressure difference occurring in a piping joint portion (a joint portion of the flow paths 311 and 321) of the gas and the liquid. This may cause the liquid to be blocked by the gas and cause only the gas to be injected from the release nozzles. The wafer is thus likely to be dried, depending on the wafer release time. The configuration of the embodiment, on the other hand, first fills the flow path 331 with only the liquid and subsequently supplies the gas to the flow path 331 with stopping the supply of the liquid. This configuration suppresses or prevents only the gas from being injected from the release nozzles and thereby suppresses the wafer from being dried. Furthermore, the configuration of the embodiment starts injection of the pressurized fluid after elapse of a predetermined delay time since the membrane swelling start timing. This prevents the liquid filled in the flow path from being used up prior to the wafer release and thereby prevents only the gas from being injected to the wafer. This effectively suppresses the wafer from being dried.

[Directions of Release Nozzles]

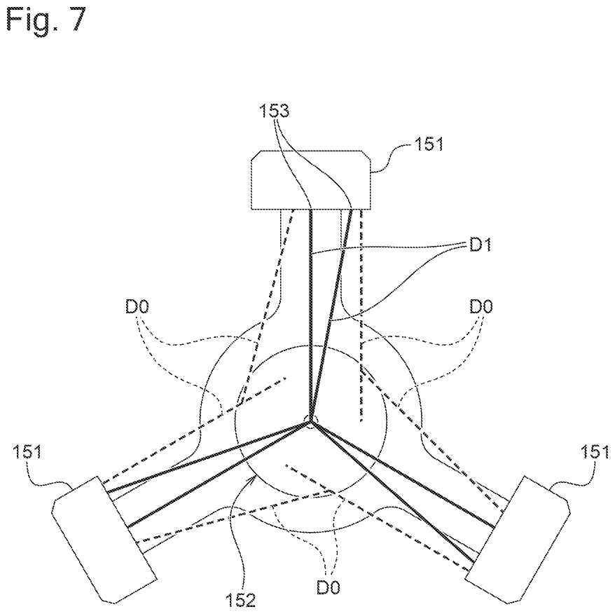

FIG. 7 is a plan view of the pusher showing the directions of the release nozzles. Lines D0 indicate injection directions of release nozzles according to a comparative example. Lines D1 indicate injection directions of the release nozzles 153 according to this embodiment. As shown in this drawing, the injection directions D0 of the release nozzles according to the comparative example are set not to concentrate the pressurized fluid on the center of the wafer, in order to prevent hovering of the wafer. Hovering herein denotes a phenomenon that the wafer W is not seated on the push stage 152 but is floated even after being separated from the membrane 204 by concentrating a gas or a pressurized fluid including a gas onto the center of the wafer. It is expected that such hovering is related to an injection time of the pressurized fluid to the wafer in the course of a wafer release operation. The configuration of the embodiment, on the other hand, enables the wafer to be released in a shorter injection time of the pressurized fluid by two-step pressurizations of the membrane (overall pressurization+center portion pressurization) and/or adjustment of the injection start timing of the pressurized fluid. This configuration prevents hovering in the course of wafer release even when the gas or the pressurized fluid including the gas is directed toward the center of the wafer. The configuration of the embodiment sets the injection directions of the release nozzles 153 toward the center of the wafer W. This enables the pressurized fluid to be injected onto a contact location between the membrane and the wafer with the higher efficiency and further reduces a wafer release time (a time period required for the wafer release). In the case where only the liquid is injected as the pressurized fluid, no problem of hovering occurs. Setting the injection directions of the release nozzles 153 toward the center of the wafer W reduces the wafer release time.

[Principle of Wafer Release]

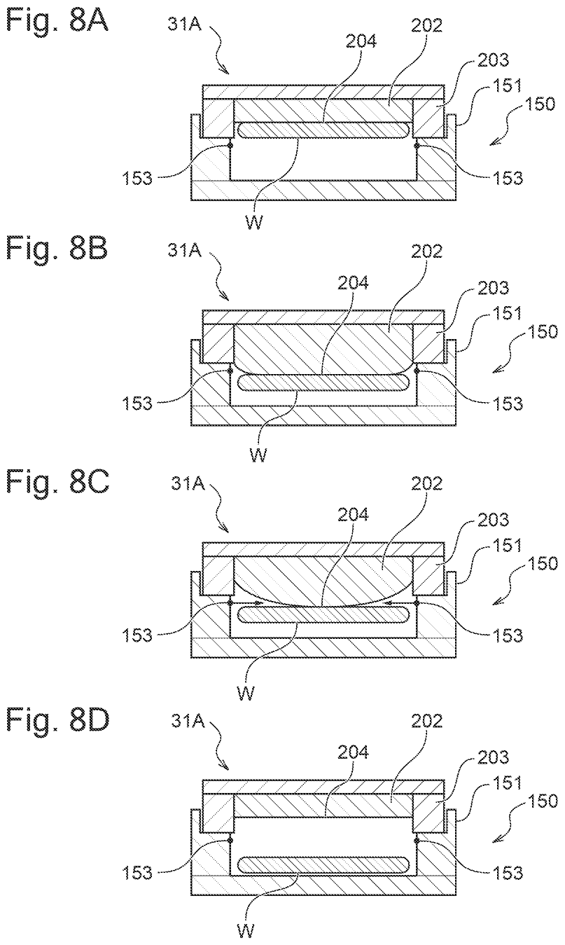

FIG. 8A to FIG. 8D are explanatory diagrams illustrating a process of releasing the wafer from the top ring. In order to avoid the complications of the drawings, the push stage 152 and the seating sensors 154 are omitted from the illustrations of these drawings.

As described above, after completion of the wafer treatment process on the polishing pad 10, the process moves the top ring 31A with the wafer W sucked thereto to the pusher 150 and causes the retainer ring 203 of the top ring 31A to be engaged with the top ring guide 151 of the pusher 150 (as shown in FIG. 8A).

The process subsequently stops vacuum suction of the wafer W by the top ring 31A, supplies the gas to all the areas 205 to 208 of the membrane 204 to pressurize and swell the entirety of the membrane 204 (overall pressurization step, as shown in FIG. 8B). Pressurization/swelling of the entirety of the membrane means that all the areas of the membrane are equally swollen to have substantially the same heights. Accordingly, the overall pressurization step is also referred to as overall swelling step. In this state, the height of the contact location between the membrane 204 and the wafer W is substantially aligned with the height of the release nozzles 253 (i.e., is made substantially equal to or slightly lower than the height of the release nozzles 253). The membrane 204 has the higher swellability on the center side and has the decreasing swellability toward the outer circumferential side. In order to swell all the areas of the membrane equally, one exemplified procedure may regulate the pressurizations in the respective areas, such as to minimize the pressure in the area 1 on the center-most side and sequentially increase the pressures in the areas toward the outer circumferential side. After pressurization of the entire membrane, the process causes all the areas 205 to 208 of the membrane 204 to once communicate with the atmosphere and thereby resets the internal pressures of all the areas 205 to 208.

The process subsequently supplies the gas to the respective areas 205 to 208 of the membrane 204, such as to pressurize/swell the center portion of the membrane 204 (center portion pressurization step, as shown in FIG. 8C). This contracts the contact location (sticking area) between the membrane 204 and the wafer W toward the center portion of the wafer W. In this state, the height of the contact location between the membrane 204 and the wafer W is hardly changed from the height in the overall pressurization step and is substantially aligned with the height of the release nozzles 253. One exemplified procedure may increase the pressure in the first area 205 on the center-most side to four times or higher of the pressure in the first area 205 in the overall pressurization step, while decreasing the pressures in the other areas 206 to 208 from the pressures in the overall pressurization step. This implements the center portion pressurization step to increase the pressure in the first area 205 to be higher than the pressures in the other areas 206 to 208 and to swell the first area 205 more significantly than the other areas. The center portion pressurization step is thus also referred to as center portion swelling step. In the case where the membrane has a large number of areas in the pressure chamber, multiple areas including a center-most first area may be pressurized to have a higher pressure than pressures in the other areas. In this illustrated example, the first area 205 is specified as the range of pressurization to the higher pressure than the pressures in the other areas (as the center portion of the membrane) in the center portion pressurization step. In the case where the center portion of the membrane 204 is defined on the basis of the radius of the membrane 204, an area included in a range from the center (center point) of the membrane 204 to a length in a radial direction of not greater than 50% of the radius may be pressurized as the center portion of the membrane. More preferably, an area included in a range from the center of the membrane 204 to a length in the radial direction of 40% to 50% of the radius may be pressurized as the center portion of the membrane. For example, among the total of four areas 205, 206, 207 and 208 shown in FIG. 3, the first area 205 and the second area 206 may be specified as the center portion of the membrane to be pressurized by a higher pressure than the pressure applied for pressurizations in the other areas.

As described above, the membrane has the higher swellability on the center side. In the case where the respective areas are pressurized by an identical pressure, the area on the center side of the membrane is swollen to be slightly protruded from the other areas. The center portion pressurization step according to the embodiment is, however, different from this procedure but makes the pressure in the area on the center side of the membrane higher than the pressures in the other areas, so as to make the center side of the membrane protruded more prominently. This configuration sufficiently reduces the area of the contact location between the membrane and the wafer and accelerates the wafer release.

In the course of at least the center portion pressurization step, the process injects or sprays the pressurized fluid F from the release nozzles 153 toward the contract location between the membrane and the wafer (as shown in FIG. 8C). This causes the wafer W to be released from the membrane 204 (as shown in FIG. 8D). The wafer W released from the membrane 204 falls down on the push stage 152 and is detected by one or a plurality of seating sensors 154 on the push stage 152 (as shown in FIG. 4 and FIG. 5). The detection of the wafer W by the seating sensors 54 indicates detection of release of the wafer W. For example, in the case where the three seating sensors 154 are provided as shown in FIG. 4 and FIG. 5, the detection of the wafer by all the seating sensors 154 may be specified as detection of the wafer release. In FIG. 8A to FIG. 8D, the injection of the pressurized fluid is started in the center portion pressurization step (shown in FIG. 8C). As described later, however, the injection of the pressurized fluid may be started in the middle of the overall pressurization step after elapse of a predetermined delay time since the start of the overall pressurization step (shown in FIG. 8B).

When a wafer release is not detected in one center portion pressurization step, the center portion pressurization step may be performed repeatedly with a reset step of resetting the pressures in all the areas of the membrane 204 between the center portion pressurization steps, until detection of a wafer release. In the case where a wafer release is not detected during repetition of a predetermined number of (one or more) center portion pressurization steps, the process may reset the pressures in all the areas of the membrane 204 and repeat the control cycle from the overall pressurization step (shown in FIG. 8A to FIG. 8C). The number of repetition of the control cycles reaches a predetermined upper limit number of times, the process may give an alarm and terminate the wafer release process (error process).

[Control Cycle of Wafer Release]

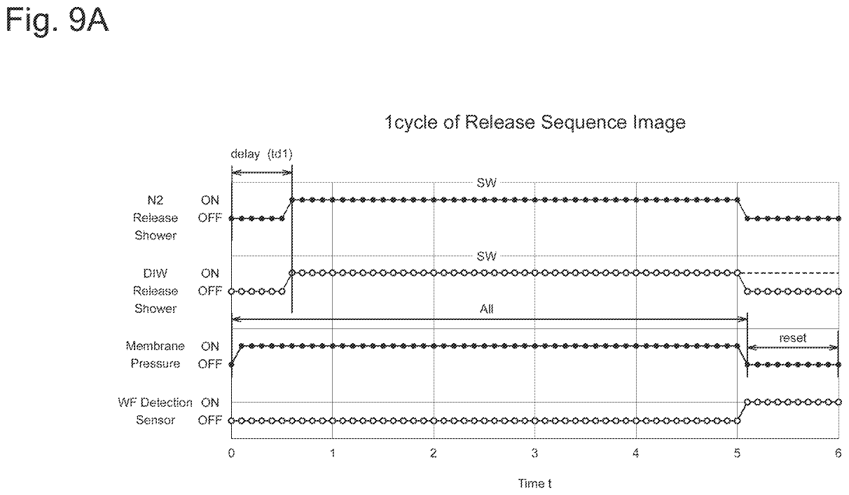

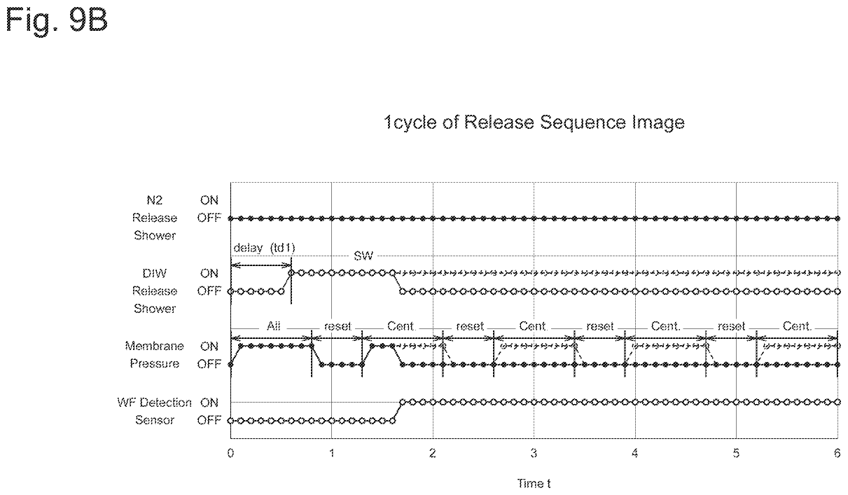

FIG. 9A is a time chart showing one control cycle in a sequence of wafer release process according to a comparative example. FIG. 9B is a time chart showing one control cycle in a sequence of wafer release process according to the embodiment. In the description hereof, the injection start timing of the pressurized fluid F is an injection start timing (=an injection delay time) of the pressurized fluid F based on a swelling start time of the membrane 204 (a start of the release process, t=0 in FIG. 9A and FIG. 9B).

In the comparative example (shown in FIG. 9A), the directions of the release nozzles 153 were set to the directions D1 shown in FIG. 7, and DIW and nitrogen gas were supplied as the pressurized fluid F (by simultaneously opening valves of DIW and nitrogen gas). The injection start timing of the pressurized fluid F was set to 0.5 seconds, and the membrane 204 was swollen by only the overall pressurization step.

In the embodiment (shown in FIG. 9B), the directions of the release nozzles 153 were set to the directions D1 shown in FIG. 7, and only DIW was supplied as the pressurized fluid F. The injection start timing of the pressurized fluid F was set to 0.5 seconds, and the membrane 204 was swollen by an overall pressurization step (A11) and center portion pressurization steps (Cent.). The reduction of the wafer release time is thought to be mainly attributed to the two-step pressurizations (overall pressurization+center portion pressurization). In the embodiment (shown in FIG. 9B), similar results to those in the case where only DIW is injected as the pressurized fluid F are accordingly expected in the case where a mixed fluid of DIW and nitrogen gas is injected as the pressurized fluid F and in the case where only the nitrogen gas is injected as the pressurized fluid F.

As shown in FIG. 9A, one control cycle in the sequence of wafer release process according to the comparative example includes an overall pressurization step of the membrane 204 (A11) and a release shower step (SW) of injecting the pressurized fluid F (DIW and nitrogen gas). This one control cycle is repeatedly performed until detection of a wafer release. In response to detection of a wafer release, the wafer release process is terminated to open all the areas of the membrane 204 to the atmospheric pressure and reset the pressures in all the areas and to stop the injection of the pressurized fluid F (DIW and nitrogen gas) (t=5.1 seconds in FIG. 9A).

In the example of FIG. 9A, the wafer release process starts swelling of the membrane 204 (the overall pressurization step) at a time t=0 (a change from OFF to ON in a membrane pressure curve in FIG. 9A) and starts injection of the pressurized fluid F from the release nozzles 153 at an injection start timing t=td=0.5 seconds (changes from OFF to ON in a DIW release shower curve and an N2 release shower curve in FIG. 9A). When release of the wafer is detected by the seating sensors 154 (a change from OFF to ON in a wafer detection sensor curve in FIG. 9A), the wafer release process terminates the pressurization of the membrane 204 (a change from ON to OFF in the membrane pressure curve in FIG. 9A), opens all the areas of the membrane 204 to the atmospheric pressure (reset), and stops the injection of the pressurized fluid F (changes from ON to OFF in the DIW release shower curve and the N2 release shower curve in FIG. 9A). In the example of FIG. 9A, a wafer release was detected in the first control cycle, and the wafer release time was approximately 5.1 seconds. The wafer release time denotes a time period required for release of the wafer and is defined as a time period from a start time of the pressurization of the membrane 204 to detection of the wafer release.

As shown in FIG. 9B, one control cycle in the sequence of wafer release process according to the embodiment includes an overall pressurization step of the membrane 204 (A11) and a predetermined number of (one or multiple times of) the center portion pressurization steps of the membrane 204 (Cent.) and also includes a release shower step (SW) of injecting or spraying the pressurized fluid F (DIW). This one control cycle is repeatedly performed until detection of a wafer release. In response to detection of a wafer release, the wafer release process is terminated to open all the areas of the membrane 204 to the atmospheric pressure and reset the pressures in all the areas (reset) and to stop the injection of the pressurized fluid F (DIW) (t=1.7 seconds in FIG. 9B).

In the example of FIG. 9B, the wafer release process starts the overall pressurization step of the membrane 204 (A11) at the time t=0 (a change from OFF to ON in a membrane pressure curve in FIG. 9B) and starts injection of the pressurized fluid F from the release nozzles 153 at an injection start timing t=td=0.5 seconds (a change from OFF to ON in a DIW release shower curve in FIG. 9B). After termination of the overall pressurization step of the membrane 204 (A11), the wafer release process performs a reset step (reset) to open all the areas of the membrane 204 to the atmosphere and reset the pressures in all the areas of the membrane 204 to the atmospheric pressure. The wafer release process then starts the center portion pressurization step of the membrane 204 (Cent.). In the center portion pressurization step, the center portion of the membrane 204 (the first area 205) is pressurized, while the pressurized fluid F is injected from the release nozzles 153 to the contact location between the membrane and the wafer. This releases the wafer W from the membrane 204 (a change from OFF to ON in a wafer detection sensor curve in FIG. 9B). The release of the wafer is detected by the seating sensors 154. When release of the wafer is detected by the seating sensors 154, the wafer release process terminates the center portion pressurization step of the membrane 204 (Cent.) (a change from ON to OFF in the membrane pressure curve (a solid line curve) in FIG. 9B), opens all the areas of the membrane 204 to the atmospheric pressure, and stops the injection of the pressurized fluid F (a change from ON to OFF in the DIW release shower curve (a solid line curve) in FIG. 9B). In the example of FIG. 9B, a wafer release was detected in the first control cycle, and the wafer release time was approximately 1.7 seconds. Broken line curves in the DIW release shower curve and in the membrane pressure curve in FIG. 9B show the control in the case where a wafer release is not detected.

[Flowchart of Wafer Release Process]

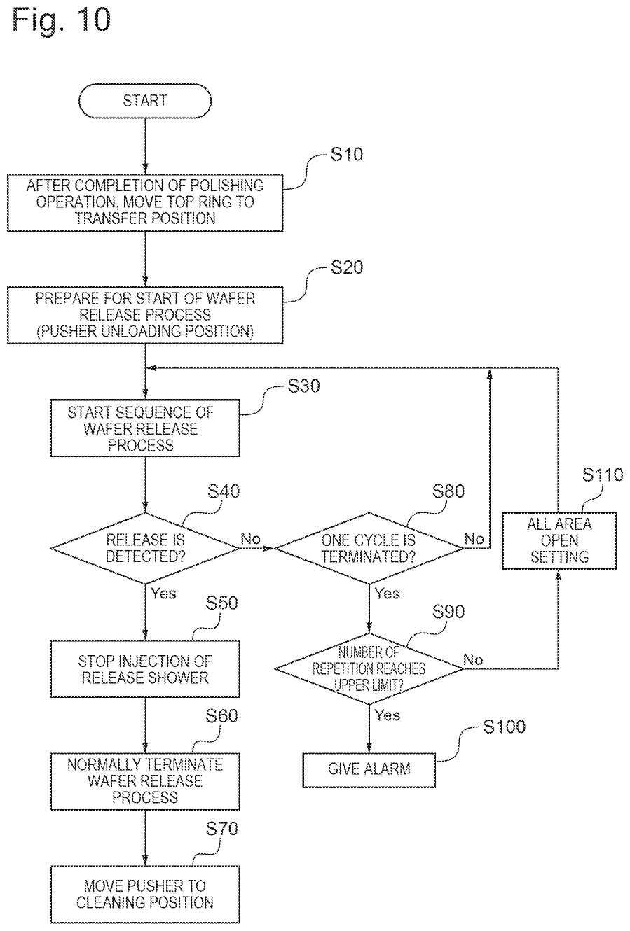

FIG. 10 is a flowchart showing the wafer release process according to this embodiment.

At step S10, after completion of a polishing operation, the top ring 31A with the wafer held thereby is moved to the transfer position (above the pusher 150).

At step S20, the pusher 150 is moved up to be engaged with the top ring 31A. This completes preparation for a start of the wafer release process.

At step S30, one control cycle in the sequence of wafer release process described above with referring to FIG. 9B is started and performed. More specifically, the one control cycle performs the overall pressurization step of the membrane 204 and the predetermined number of center portion pressurization steps and also performs the release shower step of injecting or spraying the pressurized fluid F to the contact location between the membrane and the wafer as shown in FIG. 9B.

At step S40, the wafer release process determines whether a release of the wafer is detected at every predetermined time interval. The detection of the wafer release may be determined, for example, by determining whether or not all the plurality of seating sensors 154 detect the wafer. When a release of the wafer is detected, the wafer release process stops the injection of the pressurized fluid F (step S50) and is terminated by stopping the pressurization of the membrane 204 and resetting the pressures in all the areas of the membrane 204 to the atmospheric pressure (step S60). The pusher 150 is then moved down to be separated from the top ring 31A and is moved to a cleaning position (a position where the wafer is transferred to the cleaning module 4) (step S70).

When a release of the wafer is not detected at step S40, the wafer release process proceeds to step S80. At step S80, it is determined whether one control cycle in the sequence of wafer release process is terminated. When it is determined at step S80 that one control cycle is not yet terminated, the wafer release process returns to step S30 to continue the currently ongoing one control cycle. When it is determined at step S80 that one control cycle is terminated, on the other hand, the wafer release process proceeds to step S90.

At step S90, the wafer release process determines whether the number of repetition of the one control cycle reaches an upper limit number of times. When it is determined that the number of repetition of the one control cycle does not yet reach the upper limit number of times, the wafer release process proceeds to step S110. The wafer release process performs an all area open setting to open all the area of the membrane 204 to the atmospheric pressure (corresponding to the reset step of FIG. 9B) at step S110, and subsequently proceeds to step S30 to start and perform next one control cycle.

When it is determined at step S90 that the number of repetition of the one control cycle reaches the upper limit number of times, on the other hand, the wafer release process gives an alarm and performs an error process (step S100).

[Difference in Wafer Release Time by Injection Start Timing of Release Shower]

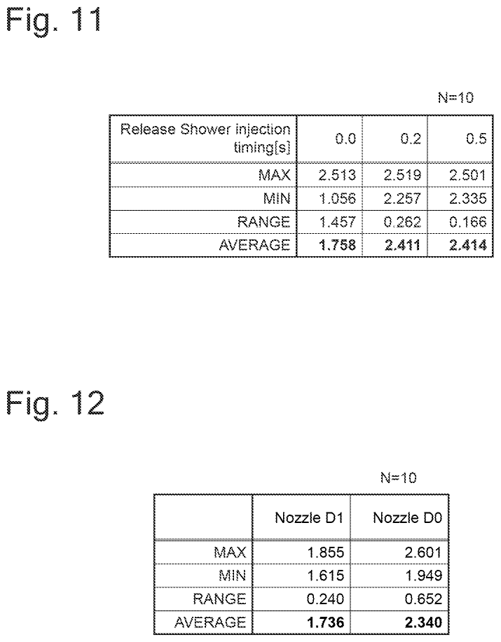

FIG. 11 is a diagram illustrating a measurement example that measures a difference in wafer release time by the injection start timing of the pressurized fluid. In this diagram, respective numerical values (0.0, 0.2, and 0.5) on the uppermost row are injection start timings of the release shower (the pressurized fluid). The injection start timing corresponds to a delay time from a start timing of the overall pressurization step of the membrane 204 to the injection start timing of the pressurized fluid F. This measurement example performed a total of ten measurements (N=10). MAX denotes a maximum value among the total of ten measurement values; MIN denotes a minimum value among the total of ten measurement values; and RANGE denotes a difference between MAX and MIN, i.e., a range of variation of the measurement values. AVERAGE denotes an average value of the total of ten measurement values. Each measurement performed the two-step pressurizations (the overall pressurization and the center portion pressurization) of the membrane shown in FIG. 9B and measured the wafer release time with setting the directions of the release nozzles to the directions D0 shown in FIG. 7 and changing an injection start timing of the pressurized fluid (delay time) td1 to 0.0 second, 0.2 seconds and 0.5 seconds. In all the cases, the fluid mixture of DIW and nitrogen gas was used as the pressurized fluid F (DIW was pushed out to be injected by the nitrogen gas).

According to the measurement results shown in FIG. 11, the injection start timing of the release shower (delay time) equal to 0.0 second has the shortest average wafer release time (AVERAGE) but has the largest variation of the measurement value (RANGE), which indicates the low stability (reproducibility) of the wafer release process. This embodiment accordingly employs the delay time of 0.5 seconds by taking into account the stability of the wafer release time.

In the configuration of pushing out the liquid by the gas to inject the pressurized fluid F, when the delay time is equal to 0.0 second, DIW filled in the flow path and injected from the release nozzles is run out prior to a release of the wafer, and afterwards only the nitrogen gas is sprayed onto the wafer. The wafer is thus likely to be dried. When the delay time of 0.5 seconds is employed, on the other hand, the power of DIW pushed out by the nitrogen gas is effectively and efficiently used for the wafer release and thus enables the wafer to be released in a DIW injection time. Completion of the wafer release in the DIW injection time suppresses the wafer from being dried and thereby suppresses the occurrence of a defect.

[Difference in Wafer Release Time by Directions of Release Nozzles]

FIG. 12 is a diagram illustrating a measurement example that measures a difference in wafer release time by the directions of the release nozzles. In this diagram, Nozzle D1 is an example that employs the directions indicated by the lines D1 of the embodiment shown in FIG. 7 as the directions of the release nozzles. Nozzle D0 is an example that employs the directions indicated by the lines D0 of the comparative example shown in FIG. 7 as the directions of the release nozzles. These examples differ in only the directions of the release nozzles and otherwise have the same conditions. Both the examples Nozzle D1 and Nozzle D0 performed the two-step pressurizations (the overall pressurization and the center portion pressurization) of the membrane shown in FIG. 9B, set the injection start timing td1 of the pressurized fluid to 0.5 seconds, and used the fluid mixture of DIW and nitrogen gas as the pressurized fluid F (DIW was pushed out to be injected by the nitrogen gas). This measurement example also performed a total of ten measurements (N=10), like the measurement example of FIG. 11. The meanings of MAX, MIN, RANGE and AVERAGE are the same as those in FIG. 11.

According to the measurement results shown in FIG. 12, the configuration of setting the directions of the release nozzles to the directions D1 (the directions of the release shower/pressurized fluid toward the center of the wafer) significantly shortens the wafer release time and suppresses a variation in the wafer release time, compared with the configuration of setting the directions of the release nozzles to the direction D0 (the directions of the release shower/pressurized fluid that do not concentrate on the center of the wafer).

The configuration of the embodiment described above injects or sprays the pressurized fluid to the contact location between the membrane and the wafer in the state that the center portion of the membrane is pressurized to reduce the area of the contact location between the membrane and the wafer. This shortens the wafer release time. Shortening the wafer release time suppresses the wafer surface from being dried by the pressurized fluid and thereby suppresses the occurrence of a defect.

Furthermore, the configuration of the embodiment pressurizes the entire membrane prior to the pressurization of the center portion of the membrane. This reduces the stress placed on the wafer.

In the embodiment described above, the configuration of injecting only the liquid (for example, DIW) as the pressurized fluid effectively suppresses/prevents the wafer surface from being dried and suppresses/prevents the occurrence of a defect. In the case of injecting only the liquid (for example, DIW) as the pressurized fluid, the pressure of the pressurized fluid becomes lower and is thus likely to increase the wafer release time. The combination of the overall pressurization of the membrane and the center portion pressurization of the membrane described above, however, swells the membrane promptly and reduces the contact area between the membrane and the wafer. The injection of the liquid in this state shortens the wafer release time. The configuration of the embodiment thus effectively suppresses/prevents the wafer surface from being dried even when only the liquid is injected as the pressurized fluid, while avoiding the problem of the increase in the wafer release time.

In the embodiment described above, in the configuration of filling the liquid (for example, DIW) in the flow path of the release nozzles and pushing out and injecting the liquid from the release nozzles by the gas (for example, nitrogen gas), the liquid filled in the flow path may be run out prior to release of the wafer to cause injection of only the gas. Starting the injection from the release nozzles (injection of the liquid by the gas) after elapse of an appropriate delay time since the swelling start time of the membrane, however, enables the wafer to be released during the injection time of the liquid, before the liquid filled in the flow path is run out. This suppresses the wafer from being dried and thereby suppresses the occurrence of a defect.

Furthermore, the configuration of employing the combination of the overall pressurization of the membrane with the center portion pressurization of the membrane described above, and regulating the delay time of the pressurized fluid injection, shortens the wafer release time with the high reproducibility. This suppresses the wafer surface from being dried and thereby suppresses the occurrence of a defect even when only the gas is injected as the pressurized fluid.

The configuration of the embodiment described above sets the directions of the release nozzles toward the center of the wafer. This enables the pressurized fluid to be concentrated on the contact location between the membrane and the wafer and further shortens the wafer release time.

The configuration of the embodiment described above regulates the injection start timing/delay time of the release shower (pressurized fluid) to the appropriate value. This shortens the wafer release time, while avoiding reduction of the stability/reproducibility of the wafer release process.

In the configuration of the embodiment described above, the release nozzles are connected in a switchable manner with the liquid supply source and with the gas supply source. This configuration enables only the liquid, only the gas, and both the liquid and the gas to be injected as the pressurized fluid, in response to the user's request.

### OTHER EMBODIMENTS

(1) The above embodiment describes the case that the pusher is the substrate transfer apparatus as an example. The substrate transfer apparatus may, however, be a retainer ring station made of a ring-shaped member that is engaged with the top ring. The retainer ring station has a shape substantially corresponding to the ring-shaped portion of the top ring guide 151 of the pusher 150 shown in FIG. 5. Like the top ring guide 151 of the pusher 150, the release shower nozzles 153 may be provided on an inner circumferential surface of the retainer ring station. In the case of using the retainer ring station, the wafer may be transferred by a conveyance or transfer stage or a hand of a transporter.

(2) The method of the wafer release process described in the above embodiment is not limited to the wafer and the polishing apparatus but may be applied to any substrate processing apparatus having a mechanism of holding any substrate on a surface of a membrane.

At least the following aspects are provided from the description of the above embodiments.

[1] According to one aspect, there is provided an apparatus for polishing, comprising: a polishing table configured to support a polishing pad; a substrate holding member having a substrate holding surface and a pressure chamber, which are made of an elastic membrane, wherein the pressure chamber has a plurality of areas arranged concentrically and a substrate is pressed against the polishing pad by a pressure in the pressure chamber; a pressure regulator configured to regulate a pressure of a gas that is supplied to the pressure chamber of the substrate holding member; one or a plurality of release nozzles configured to inject a pressurized fluid; and a control device configured to perform a substrate release process of releasing the substrate from the elastic membrane, the substrate release process controlling the pressure regulator to pressurize entirety of the elastic membrane by pressurizing all the areas in the pressure chamber and subsequently pressurize a center portion of the elastic membrane by pressurizing the pressure chamber such as to make a pressure in one or multiple areas on a center side, which include an area at a center of the pressure chamber, higher than pressures in other areas, wherein meanwhile the substrate release process controls the one or plurality of release nozzles to inject the pressurized fluid to a contact location between the elastic membrane and the substrate.

The substrate holding member is configured to hold the substrate by the substrate holding surface.

An injection start timing of the pressurized fluid may be at the start of the pressurization of the entirety of the elastic membrane or during the pressurization of the entirety of the elastic member.

The “one or multiple areas on the center side, which include the area at the center of the pressure chamber” may be one or multiple areas (including the area at the center of the pressure chamber) included in a range from the center of the pressure chamber (the elastic membrane, the substrate holding surface) to a length in a radial direction of not greater than 50% of a radius of the pressure chamber. More preferably, the “one or multiple areas on the center side, which include the area at the center of the pressure chamber” may be one or multiple areas (including the area at the center of the pressure chamber) included in a range from the center of the pressure chamber to a length in the radial direction of 40% to 50% of the radius of the pressure chamber. For example, in the case of a pressure chamber (the elastic membrane, the substrate holding surface) having a radius r, one or multiple areas included in a circular range having a radius of not greater than 0.5 r from the center (in another example, a radius of not greater than 0.45 r) may be pressurized as the center portion of the pressure chamber (the elastic membrane, the substrate holding surface). The one or multiple areas to be pressurized may be continuous areas or may be discrete areas.

The configuration of this aspect injects or sprays the pressurized fluid to the contact location between the elastic membrane and the substrate in the state that the center portion of the elastic membrane is pressurized to reduce the area of the contact location between the elastic membrane and the substrate. This shortens a substrate release time. Shortening the substrate release time suppresses a substrate surface from being dried by the pressurized fluid and thereby suppresses the occurrence of a defect. The entire elastic membrane is evenly swollen, prior to swelling of the center portion of the elastic membrane. This reduces the stress placed on the substrate.

The configuration of this aspect pressurizes the area of the high swellability on the center side of the membrane (the pressure chamber) to have the higher pressure than the pressure in the area of the low swellability on the outer side. This causes the center portion of the membrane to be protruded more prominently and effectively reduces the area of the contact location between the membrane and the substrate. In the case where the pressure chamber has a large number of areas, multiple areas including a center area may be pressurized to have a higher pressure than pressures in the other areas. This regulates the degree of protrusion in the center portion of the membrane and reduces the stress placed on the substrate.

[2] According to one aspect, the apparatus for polishing may further comprise a detection device configured to detect a release of the substrate from the elastic membrane. The control device may be configured to perform an overall pressurization step of pressurizing the entirety of the elastic membrane and subsequently perform a center portion pressurization step of pressurizing the center portion of the elastic membrane a predetermined number of times, and the control device may terminate the substrate release process when the detection device detects the release of the substrate from the elastic membrane. The detection device may be, for example, a contact sensor such as a seating sensor and may be configured to monitor pressures in the membrane and detect a release of the substrate.

In the case where the substrate is not released in one center portion pressurization step, the configuration of this aspect repeats a process of performing the center portion pressurization step after resetting the pressurization of the elastic membrane (by opening the pressure chamber of the elastic membrane to the atmosphere), so as to release the substrate.

[3] According to one aspect, in the apparatus for polishing, the control device may be configured to perform one control cycle repeatedly up to a predetermined upper limit number of times, wherein one control cycle performing the overall pressurization step and subsequently performing the center portion pressurization step the predetermined number of times, and the control device may terminate the substrate release process when the detection device detects the release of the substrate from the elastic membrane.

In the case where the substrate is not released in one control cycle, the configuration of this aspect repeats the control cycle, so as to release the substrate.

[4] According to one aspect, in the apparatus for polishing, the control device may control the release nozzle to start injection of the pressurized fluid during the pressurization of the entirety of the elastic membrane after elapse of a predetermined delay time since a start of the pressurization of the entirety of the elastic membrane.

The configuration of this aspect starts injection of the pressurized fluid after elapse of an appropriate delay time since a start of pressurization of the elastic membrane. This suppresses a variation in the substrate release time and improves the stability (reproducibility) of the substrate release process. In the case where the liquid is filled in a flow path of the release nozzle and is pushed out and injected from the release nozzle by the gas, the injection from the release nozzle (injection of the liquid by the gas) is started after elapse of an appropriate delay time since a start of swelling of the membrane. This prevents the liquid filled in the flow path from being used up prior to a release of the substrate (wafer) and prevents only the gas from being injected but enables the substrate to be released during an injection time of the liquid. This suppresses the substrate from being dried and thereby prevents the occurrence of a defect.

[5] According to one aspect, in the apparatus for polishing, the control device may pressurize the center portion of the elastic membrane by pressurizing the pressure chamber such as to make a pressure in the area at the center of the pressure chamber higher than pressures in other areas.

The configuration of this aspect pressurizes the pressure chamber such that only a single area at the center of the pressure chamber has the higher pressure than the pressures in the other areas. This effectively reduces the contact area between the elastic membrane and the substrate and further shortens the substrate release time.

[6] According to one aspect, in the apparatus for polishing, the one or multiple areas on the center side, which include the area at the center of the pressure chamber, may be one or multiple areas included in a range from the center of the pressure chamber to a length in a radial direction of not greater than 50% of a radius of the pressure chamber.

The configuration of this aspect effectively achieves a balance between the reduction of stress placed on the substrate and the reduction of the contact area between the elastic membrane and the substrate.

[7] According to one aspect, in the apparatus for polishing, the one or multiple areas on the center side, which include the area at the center of the pressure chamber, may be one or multiple areas included in a range from the center of the pressure chamber to a length in the radial direction of 40% to 50% of the radius of the pressure chamber.

The configuration of this aspect more effectively achieves a balance between the reduction of stress placed on the substrate and the reduction of the contact area between the elastic membrane and the substrate.

[8] According to one aspect, in the apparatus for polishing, an injection direction of the one or plurality of release nozzles may be directed toward the center of the substrate.

The configuration of this aspect enables the pressurized fluid to be concentrated on a contact location between the elastic membrane and the substrate that is contracted to the center of the elastic membrane/substrate by the center portion pressurization. This further shortens the substrate release time.

[9] According to one aspect, in the apparatus for polishing, the pressurized fluid injected from the release nozzle may be a liquid. For example, pure water such as DIW or another liquid that does not affect a semiconductor manufacturing process may be used as the liquid.

The configuration of this aspect uses the liquid as the pressurized fluid that is injected to the contact location between the elastic membrane and the substrate. This more effectively suppresses the substrate surface from being dried and thereby suppresses the occurrence of a drying-induced defect.

[10] According to one aspect, in the apparatus for polishing, the pressurized fluid injected from the release nozzle may be a gas. For example, an inert gas such as nitrogen gas or another gas that does not affect the semiconductor manufacturing process may be used as the gas.

The configuration of pressurizing the center portion of the elastic membrane and injecting the pressurized fluid shortens the substrate release time. Even when the gas is used as the pressurized fluid, this configuration suppresses the substrate surface from being dried and thereby suppresses the occurrence of a drying-induced defect.

[11] According to one aspect, in the apparatus for polishing, the pressurized fluid injected from the release nozzle may be a liquid and a gas.

The configuration of pressurizing the center portion of the elastic membrane and injecting the pressurized fluid shortens the substrate release time. Even when the liquid and the gas are used as the pressurized fluid, this configuration suppresses the substrate surface from being dried and thereby suppresses the occurrence of a drying-induced defect.

[12] According to one aspect, in the apparatus for polishing, the release nozzle may be connected with a liquid supply source and with a gas supply source to inject a liquid and/or a gas as the pressurized fluid.

The configuration of this aspect enables a liquid, a gas or a fluid mixture of a liquid and a gas to be selected as the pressurized fluid, in response to a user's request.

[13] According to one aspect, there is provided a method of polishing a substrate by using a substrate holding member having a substrate holding surface and a pressure chamber, which are made of an elastic membrane, wherein the pressure chamber has a plurality of areas arranged concentrically. The method comprises: a step of pressing the substrate against a polishing pad by a pressure in the pressure chamber and moving the substrate and the polishing pad relative to each other to polish the substrate; a step of holding the substrate after being polished, onto the substrate holding surface of the substrate holding member; and a step of releasing the substrate from the elastic membrane when the substrate is transferred from the substrate holding member to a substrate transfer apparatus. The step of releasing comprises: an overall pressurization step of pressurizing entirety of the elastic membrane by pressurizing all the areas in the pressure chamber; a center portion pressurization step of pressurizing a center portion of the elastic membrane by pressurizing the pressure chamber to make a pressure in one or multiple areas on a center side, which include an area at a center of the pressure chamber, higher than pressures in other areas; and a step of injecting the pressurized fluid to a contact location between the elastic membrane and the substrate, at least while the center portion of the elastic membrane is pressurized.

The configuration of this aspect has similar functions and advantageous effects to those described above with respect to the above aspect [1].

[14] According to one aspect, there is provided a non-volatile storage medium configured to store therein a program that causes a computer to perform a control method of an apparatus for polishing, wherein the apparatus for polishing is configured to polish a substrate by using a substrate holding member having a substrate holding surface and a pressure chamber, which are made of an elastic membrane, wherein the pressure chamber has a plurality of areas arranged concentrically. The program causes the computer to perform: a step of pressing the substrate against a polishing pad by a pressure in the pressure chamber and moving the substrate and the polishing pad relative to each other to polish the substrate; a step of holding the substrate after being polished, onto the substrate holding surface of the substrate holding member; and a step of releasing the substrate from the elastic membrane when the substrate is transferred from the substrate holding member to a substrate transfer apparatus. The step of releasing comprises: an overall pressurization step of pressurizing entirety of the elastic membrane by pressurizing all the areas in the pressure chamber; a center portion pressurization step of pressurizing a center portion of the elastic membrane by pressurizing the pressure chamber to make a pressure in one or multiple areas on a center side, which include an area at a center of the pressure chamber, higher than pressures in other areas; and a step of injecting the pressurized fluid to a contact location between the elastic membrane and the substrate, at least while the center portion of the elastic membrane is pressurized.

The configuration of this aspect has similar functions and advantageous effects to those described above with respect to the above aspect [1].

According to one aspect, there is provided an apparatus for processing a substrate, comprising: a substrate holding member having a substrate holding surface and a pressure chamber, which are made of an elastic membrane, wherein the pressure chamber has a plurality of areas arranged concentrically; a pressure regulator configured to regulate a pressure of a gas that is supplied to the pressure chamber of the substrate holding member; one or a plurality of release nozzles configured to inject a pressurized fluid; and a control device configured to perform a substrate release process of releasing the substrate from the elastic membrane, the substrate release process controlling the pressure regulator to pressurize entirety of the elastic membrane by pressurizing all the areas in the pressure chamber and subsequently pressurize a center portion of the elastic membrane by pressurizing the pressure chamber such as to make a pressure in one or multiple areas on a center side, which include an area at a center of the pressure chamber, higher than pressures in other areas, wherein meanwhile the substrate release process controls the one or plurality of release nozzles to inject the pressurized fluid to a contact location between the elastic membrane and the substrate. The apparatus for processing the substrate may include any of the technical features described in the above aspects [2] to [12].

According to one aspect, there is provided a method of processing a substrate by using a substrate holding member having a substrate holding surface and a pressure chamber, which are made of an elastic membrane, wherein the pressure chamber has a plurality of areas arranged concentrically. The method of processing the substrate comprises a step of holding the substrate after being processed, onto the substrate holding surface of the substrate holding member; and a step of releasing the substrate from the elastic membrane when the substrate is transferred from the substrate holding member to a substrate transfer apparatus, wherein the step of releasing comprises: an overall pressurization step of pressurizing entirety of the elastic membrane by pressurizing all the areas in the pressure chamber; a center portion pressurization step of pressurizing a center portion of the elastic membrane by pressurizing the pressure chamber to make a pressure in one or multiple areas on a center side, which include an area at a center of the pressure chamber, higher than pressures in other areas; and a step of injecting the pressurized fluid to a contact location between the elastic membrane and the substrate, at least while the center portion of the elastic membrane is pressurized. The method of processing the substrate may include any of the technical features described in the above aspects [2] to [12].

Although the embodiments of the present invention have been described based on some examples, the embodiments of the invention described above are presented to facilitate understanding of the present invent ion, and do not limit the present invention. The present invention can be altered and improved without departing from the subject matter of the present invention, and it is needless to say that the present invention includes equivalents thereof. In addition, it is possible to arbitrarily combine or omit the embodiments and the modifications described above and it is also possible to arbitrarily combine or omit respective constituent elements described in the claims and the specification in a range where at least a part of the above-mentioned problem can be solved or a range where at least a part of the effect is exhibited.

### REFERENCE SIGNS LIST

1 housing
2 loading/unloading module
3 polishing module
3A, 3B, 3C, 3D polishing units
4 cleaning module
5 control device
6 first linear transporter
7 second linear transporter
10 polishing pad
10a polishing surface
11 lifter
12 swing transporter
20 front loading unit
21 traveling mechanism
22 transfer robot
30B, 30C, 30D polishing tables
31A, 31B, 31C, 31D top rings (substrate holding members)
32A, 32B, 32C, 32D polishing solution supply nozzles
33A, 33B, 33C, 33D dressers
34A, 34B, 34C, 34D atomizers
30Aa table shaft
51 storage unit
100 substrate processing apparatus
111 top ring shaft
112 rotary cylinder
113 timing pulley
114 top ring rotating motor
115 timing belt
116 timing pulley
117 top ring head shaft
124 vertical moving mechanism
125 rotary joint
126 bearing
128 bridge
129 support base
130 supporting column
131, 132 vacuum sources
132 ball screw
132a threaded shaft
132b nut
138 servomotor
140 encoder
150 substrate transfer apparatus (pusher)
151 top ring guide
152 push stage
153 release nozzle
154 seating sensor
202 top ring main body
203 retainer ring
204 elastic membrane (membrane)
204a partition wall
205 first area
206 second area
207 third area
208 fourth area
209 retainer ring compression chamber
211, 212, 213, 214, 215, 221, 223, 224, 226 flow paths
225 rotary joint
230 pressure regulating unit
235 steam water separation tank
311, 321, 331 flow paths
312 liquid supply source
313, 323 valves
314 flowmeter
322 gas supply source
324 check valve

What is claimed is:

1. An apparatus for polishing, comprising:
a polishing table configured to support a polishing pad;
a substrate holding member having a substrate holding surface and a pressure chamber, which are made of an elastic membrane, wherein the pressure chamber has a plurality of areas arranged concentrically and a substrate is pressed against the polishing pad by a pressure in the pressure chamber;
a pressure regulator configured to regulate a pressure of a gas that is supplied to the pressure chamber of the substrate holding member;
one or a plurality of release nozzles configured to inject a pressurized fluid; and
a control device configured to perform a substrate release process of releasing the substrate from the elastic membrane, the substrate release process controlling the pressure regulator to pressurize entirety of the elastic membrane by pressurizing all the areas in the pressure chamber and subsequently pressurize a center portion of the elastic membrane by pressurizing the pressure chamber such as to make a pressure in one or multiple areas on a center side, which include an area at a center of the pressure chamber, higher than pressures in other areas, wherein meanwhile the substrate release process controls the one or plurality of release nozzles to inject the pressurized fluid to a contact location between the elastic membrane and the substrate.

2. The apparatus for polishing according to claim 1, further comprising:
a detection device configured to detect a release of the substrate from the elastic membrane, wherein
the control device is configured to perform overall pressurization of pressurizing the entirety of the elastic membrane and subsequently perform center portion pressurization of pressurizing the center portion of the elastic membrane a predetermined number of times, and
the control device terminates the substrate release process when the detection device detects the release of the substrate from the elastic membrane.

3. The apparatus for polishing according to claim 2,
wherein the control device is configured to perform one control cycle repeatedly up to a predetermined upper limit number of times, wherein one control cycle performing the overall pressurization and subsequently performing the center portion pressurization the predetermined number of times, and
the control device terminates the substrate release process when the detection device detects the release of the substrate from the elastic membrane.

4. The apparatus for polishing according to claim 1,
wherein the control device controls the release nozzle to start injection of the pressurized fluid during the pressurization of the entirety of the elastic membrane after elapse of a predetermined delay time since a start of the pressurization of the entirety of the elastic membrane.

5. The apparatus for polishing according to claim 1,
wherein the control device pressurizes the center portion of the elastic membrane by pressurizing the pressure chamber such as to make a pressure in the area at the center of the pressure chamber higher than pressures in other areas.

6. The apparatus for polishing according to claim 1,
wherein the one or multiple areas on the center side, which include the area at the center of the pressure chamber, are one or multiple areas included in a range from the center of the pressure chamber to a length in a radial direction of not greater than 50% of a radius of the pressure chamber.

7. The apparatus for polishing according to claim 6,
wherein the one or multiple areas on the center side, which include the area at the center of the pressure chamber, are one or multiple areas included in a range from the center of the pressure chamber to a length in the radial direction of 40% to 50% of the radius of the pressure chamber.

8. The apparatus for polishing according to claim 1,
wherein an injection direction of the one or plurality of release nozzles is directed toward the center of the substrate.

9. The apparatus for polishing according to claim 1,
wherein the pressurized fluid injected from the release nozzle is a liquid.

10. The apparatus for polishing according to claim 1,
wherein the pressurized fluid injected from the release nozzle is a gas.

11. The apparatus for polishing according to claim 1,
wherein the pressurized fluid injected from the release nozzle is a liquid and a gas.

12. The apparatus for polishing according to claim 1,
wherein the release nozzle is connected with a liquid supply source and with a gas supply source to inject a liquid and/or a gas as the pressurized fluid.

13. A method of polishing a substrate by using a substrate holding member having a substrate holding surface and a pressure chamber, which are made of an elastic membrane, wherein the pressure chamber has a plurality of areas arranged concentrically, the method comprising:
pressing the substrate against a polishing pad by a pressure in the pressure chamber and moving the substrate and the polishing pad relative to each other to polish the substrate;
holding the substrate after being polished, onto the substrate holding surface of the substrate holding member; and
releasing the substrate from the elastic membrane when the substrate is transferred from the substrate holding member to a substrate transfer apparatus, wherein
the releasing comprises:
overall pressurization of pressurizing entirety of the elastic membrane by pressurizing all the areas in the pressure chamber;
center portion pressurization of pressurizing a center portion of the elastic membrane by pressurizing the pressure chamber to make a pressure in one or multiple areas on a center side, which include an area at a center of the pressure chamber, higher than pressures in other areas; and
injecting the pressurized fluid to a contact location between the elastic membrane and the substrate, at least while the center portion of the elastic membrane is pressurized.

14. A non-volatile storage medium configured to store therein a program that causes a computer to perform a control method of an apparatus for polishing, the apparatus for polishing being configured to polish a substrate by using a substrate holding member having a substrate holding surface and a pressure chamber, which are made of an elastic membrane, wherein the pressure chamber has a plurality of areas arranged concentrically,
wherein the program causes the computer to perform:
pressing the substrate against a polishing pad by a pressure in the pressure chamber and moving the substrate and the polishing pad relative to each other to polish the substrate;
holding the substrate after being polished, onto the substrate holding surface of the substrate holding member; and
releasing the substrate from the elastic membrane when the substrate is transferred from the substrate holding member to a substrate transfer apparatus, wherein
the releasing comprises:
overall pressurization of pressurizing entirety of the elastic membrane by pressurizing all the areas in the pressure chamber;
center portion pressurization of pressurizing a center portion of the elastic membrane by pressurizing the pressure chamber to make a pressure in one or multiple areas on a center side, which include an area at a center of the pressure chamber, higher than pressures in other areas; and
injecting the pressurized fluid to a contact location between the elastic membrane and the substrate, at least while the center portion of the elastic membrane is pressurized.
